(19) United States
(12) Patent Application Publication
(10) Pub. No.: US 2008/0105459 A1
(43) Pub. Date: May 8, 2008

(54) Electronic component and wire bonding method

(75) Inventor: Tomoharu Horio, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto-shi (JP)

(21) Appl. No.: 11/978,378

(22) Filed: Oct. 29, 2007

(30) Foreign Application Priority Data
Nov. 2, 2006 (JP) 2006-298756

(51) Int. Cl. H05K 1/18; B23K 31/02

(52) U.S. Cl. 174/260; 228/225

(57) ABSTRACT

An electronic component includes an electronic element, an electrode formed on the electronic element, a connection target connected to the electrode, and a wire for connecting the electrode and the connection target to each other. A first bump and a second bump are formed on the electrode. The wire includes a crown-shaped, first bonding end and a wedge-shaped, second bonding end. The crown-shaped bonding end is held in contact with the connection target, while the wedge-shaped bonding end is sandwiched between the first bump and the second bump.

### BACKGROUND OF THE INVENTION

1. Field of the Invention

The present invention relates to an electronic component including an electronic element to which wire is bonded. The invention further relates to a wire bonding method for manufacturing such an electronic component.

2. Description of the Related Art

A conventional wire bonding method is disclosed in JP-A-2005-51031, for example. FIG. 22 of the present application illustrates how the conventional wire bonding is performed. Specifically, the electronic element 92 mounted on a substrate 91 is provided with an electrode 92a. The substrate 91 is formed with a wiring pattern including a bonding pad 91a. The electrode 92a of the electronic element 92 and the bonding pad 91a are connected to each other via a wire 93.

The connection of the wire 93 is performed by using a capillary Cp. The capillary Cp is first positioned directly above the electrode 92a of the electronic element 92. Then, a wire W is caused to project from the capillary Cp, and the projecting portion is melted to form a molten ball (not shown). Then, the capillary Cp is moved closer to the electrode 92a to cause the molten ball to adhere to the electrode 92a. As a result, the molten ball becomes a first bonding portion 93a. Then, the capillary Cp is moved away from the electrode 92a as the wire W is being dispensed, whereby the first bonding step with respect to the electrode 92a is completed.

Then, the capillary Cp is moved to the bonding pad 91a, and pressed against the bonding pad 91a with a force great enough to cut the wire W. At the same time, due to the pressing force, the end of the wire W remaining on the substrate 91 is bonded to the bonding pad 91a as a second bonding portion 93b. Then, the capillary Cp is moved away from the bonding pad 91a, whereby the second bonding step with respect to the bonding pad 91a is completed.

According to the conventional bonding method, the first bonding portion 93a becomes hemispherical, whereas the second bonding portion 93b becomes flattened, having a wedge-shaped vertical section. This configuration, however, has a problem. When thermal deformation occurs at or near the electronic element 92, a relatively large stress tends to concentrate on the second bonding portion 93b. Thus, as compared with the first bonding portion 93a, breakage is more likely to occur at the second bonding portion 93b.

### SUMMARY OF THE INVENTION

The present invention has been proposed under the circumstances described above. It is therefore an object of the present invention to provide an electronic component and a wire bonding method which are capable of preventing the breakage of a wire.

According to a first aspect of the present invention, there is provided an electronic component comprising: an electronic element provided with an electrode; a connection target connected to the electrode; a wire including a first end and a second end opposite to the first end; a first bump formed on the electrode; and a second bump connected to the first bump. The first end of the wire includes a crown-shaped bonding portion held in contact with the connection target. The second end of the wire includes a wedge-shaped bonding portion sandwiched between the first bump and the second bump.

With this arrangement, the first bump, the wedge-shaped bonding portion and the second bump are collectively bonded to the electrode. Therefore, even when a force to separate the wire from the electronic element is generated, stress does not concentrate on the wedge-shaped bonding portion of the wire, whereby the wire is prevented from breaking.

According to a second aspect of the present invention, there is provided a wire bonding method for connecting an electrode of an electronic component and a connection target to each other via a wire. The method includes the steps of: forming a first bump on the electrode of the electronic element; bonding a first end of the wire to the connection target; bonding a second end of the wire to the first bump; and forming a second bump on the second end of the wire.

In accordance with the above method, the second end of the wire is sandwiched between the first bump and the second bump. Thus, even when the second end of the wire itself has a mechanically weak shape such as a wedge shape, the first and the second bumps prevent the second end from breaking.

Other features and advantages of the present invention will become more apparent from detailed description given below with reference to the accompanying drawings.

### BRIEF DESCRIPTION OF THE DRAWINGS

FIG. 1 is a sectional view showing an example of electronic component according to the present invention;

FIG. 2 is an enlarged photograph of the electronic component shown in FIG. 1;

FIG. 3 is an enlarged photograph of the electronic component shown in FIG. 1;

FIG. 4 is a sectional view showing an initial stage in the step of forming a first bump in a wire bonding method according to the present invention;

FIG. 5 is a sectional view showing the state in which a capillary is pressed against an electrode in the wire bonding method according to the present invention;

FIG. 6 is a sectional view showing the work for moving the capillary away from the electrode in the wire bonding method according to the present invention;

FIG. 7 is a sectional view showing the work for sliding the capillary in the wire bonding method according to the present invention;

FIG. 8 is a sectional view showing the work for moving the capillary away from the electrode in the wire bonding method according to the present invention;

FIG. 9 is a sectional view showing the state in which a first bump is formed in the wire bonding method according to the present invention;

FIG. 10 is a sectional view showing an initial stage of the first bonding step in the wire bonding method according to the present invention;

FIG. 11 is a sectional view showing the state in which a capillary is pressed against a bonding pad in the wire bonding method according to the present invention;

FIG. 12 is a sectional view showing the work for moving the capillary away from the bonding pad in the wire bonding method according to the present invention;

FIG. 13 is a sectional view showing the state in which the capillary is pressed against the first bump in the wire bonding method according to the present invention;

FIG. 14 is a sectional view showing the work for moving the capillary away from the first bump in the wire bonding method according to the present invention;

FIG. 15 is a sectional view showing the state in which a second bonding step is completed in the wire bonding method according to the present invention;

FIG. 16 is an enlarged photograph of the state in which the second bonding step is completed in the wire bonding method according to the present invention;

FIG. 17 is a sectional view showing the state in which the capillary is positioned directly above the second bonding portion in the wire bonding method according to the present invention;

FIG. 18 is a sectional view showing an initial stage in the step of forming a second bump in the wire bonding method according to the present invention;

FIG. 19 is a sectional view showing the state in which the capillary is pressed against the second bonding portion in the wire bonding method according to the present invention;

FIG. 20 is a sectional view showing the state in which the capillary is slid in the wire bonding method according to the present invention;

FIG. 21 is a sectional view showing the state in which the formation of the second bump is completed in the wire bonding method according to the present invention; and

FIG. 22 is a sectional view showing an example of conventional electronic component and wire bonding method.

### DETAILED DESCRIPTION OF THE PREFERRED EMBODIMENTS

Preferred embodiments of the present invention will be described below with reference to the accompanying drawings.

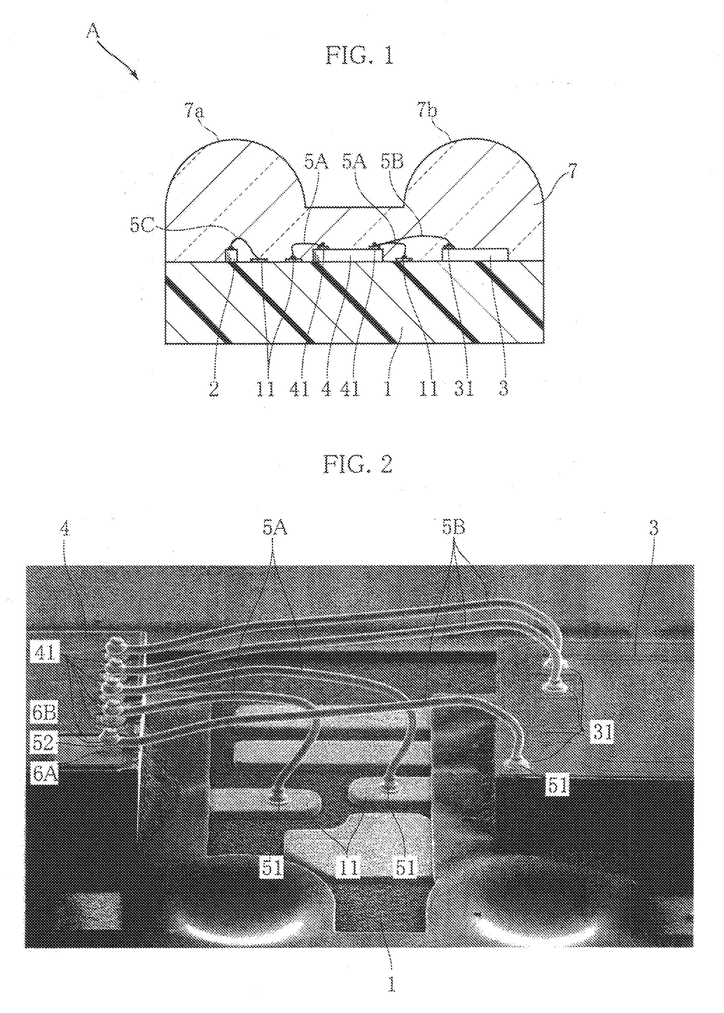

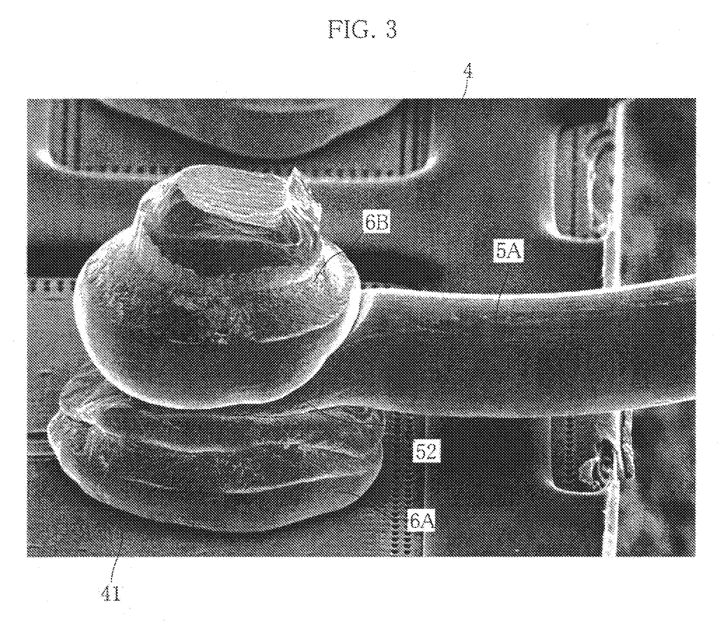

FIGS. 1-3 show an example of electronic component according to the present invention. The infrared data communication module A shown in the figures includes a substrate 1, a light emitting element 2, a light receiving element 3, a drive IC 4 and a resin package 7. The infrared data communication module A may be incorporated in e.g. a personal computer or a cell phone for performing interactive communication conforming to the IrDA. In the infrared data communication module A, wires 5A, 5B and 5C, made of e.g. Au, are used for electrically connecting the light emitting element 2, the light receiving element 3 and the drive IC 4. Of the three wires 5A, 5B and 5C, the wires 5A and 5B have the structure according to the present invention. FIGS. 2 and 3 are enlarged photographs of the infrared data communication module A. For easier understanding, these photographs do no include the resin package 7.

The substrate 1 may be made e.g. glass-fiber-reinforced epoxy resin and in the form of an elongated rectangle in plan view. The substrate 1 is formed with a wiring pattern including bonding pads 11. The wiring pattern may be formed by patterning a thin film of Cu. Wires 5A, 5C are bonded to the bonding pads 11.

The light emitting element 2 may comprise an infrared emitting diode which emits infrared rays. The light emitting element 2 is connected to the bonding pad 11 via the wire 5C.

The light receiving element 3 may comprise a PIN photodiode which detects infrared rays. Upon receiving infrared rays, the light receiving element 3 generates electromotive force corresponding to the amount of infrared rays received. As shown in FIG. 2, the light receiving element 3 is provided with a plurality of electrodes 31. To the electrodes 31, the wires 5B are bonded.

The drive IC 4 controls the light emission/reception by the light emitting element 2 and the light receiving element 3. As shown in FIG. 2, the drive IC 4 is provided with a plurality of electrodes 41. To the electrodes 41, the wires 5A, 5B are bonded.

As shown in FIG. 2, the wires 5A connect the electrodes 41 of the drive IC 4 and the bonding pads 11 of the substrate 1 to each other. The wires 5B connect the electrodes 41 of the drive IC 4 and the electrodes 31 of the light receiving element 3 to each other. The wires 5A and 5B include first bonding portions 51 and second bonding portions 52. The first bonding portions 51 of the wires 5A are bonded to the bonding pads 11 and shaped like a crown. The first bonding portions 51 of the wires 5B are bonded to the electrodes 31 and shaped like a crown. As shown in FIG. 3, each of the second bonding portions 52 is sandwiched between a first bump 6A and a second bump 6B. The first bump 6A is directly bonded to the electrode 41 and may be made of Au. The second bonding portion 52 is electrically connected to the electrode 41 via the first bump 6A. The second bump 6B is bonded to the second bonding portion 52 and may be made of Au.

The resin package 7 may be made of an epoxy resin containing a pigment and is pervious to infrared rays but not pervious to visible light. The resin package 7 may be formed by transfer molding and is provided on the substrate 1 to cover the light emitting element 2, the light receiving element 3, the drive IC 4, and the wires 5A, 5B and 5C. The resin package 7 is formed with two lenses 7a and 7b. The lens 7a is arranged to face the light emitting element 2 and serves to enhance the directivity of infrared rays from the light emitting element 2 for emission to the outside. The lens 7b is arranged to face the light receiving element 3 and serves to converge the infrared rays transmitted to the infrared data communication module A onto the light receiving surface (not shown) of the light receiving element 3.

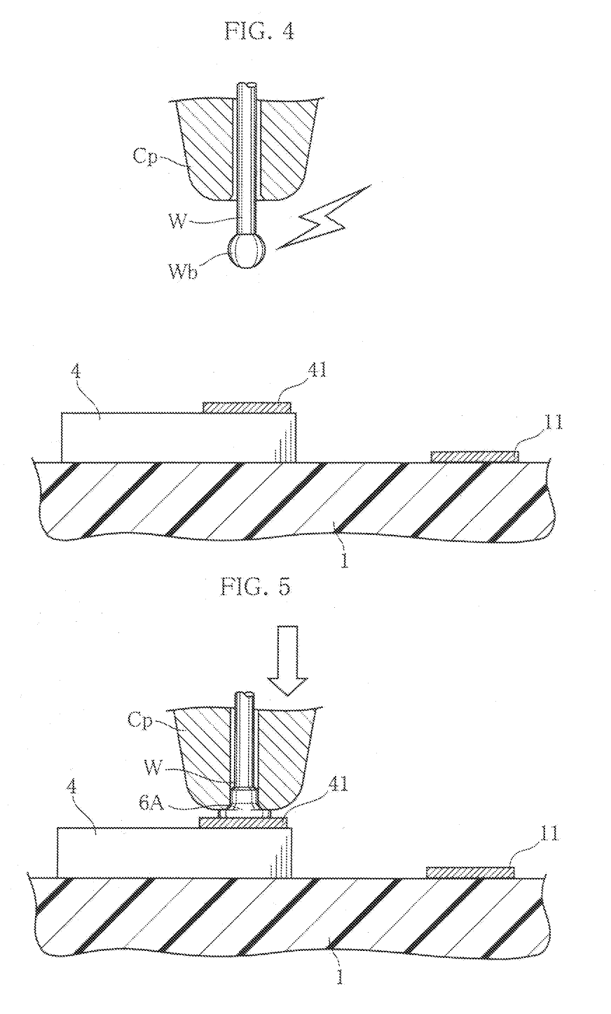

The wire bonding method to manufacture the infrared data communication module A will be described below with reference to FIGS. 4-21.

First, as shown in FIG. 4, a capillary Cp is positioned directly above the electrode 41 of a drive IC 4 bonded to a substrate 1. The capillary Cp is formed with a through-hole through which a wire W made of Au is supplied. Then, a predetermined length of wire W is fed out from the capillary C. The tip of the projecting wire W is melted by an electric spark, for example, to form a molten ball Wb.

Then, as shown in FIG. 5, the capillary Cp is lowered toward the electrode 41 and stopped when the molten ball Wb comes into sufficient contact with the electrode 41. As a result of the lowering the capillary Cp, the lower end of the molten ball Wb becomes flat by spreading against the electrode 41, and fused to the electrode 41. Meanwhile, the upper portion of the molten ball Wb is squeezed into the lower end of the through-hole in the capillary Cp. Thus, a first bump 6A is formed on the electrode 41.

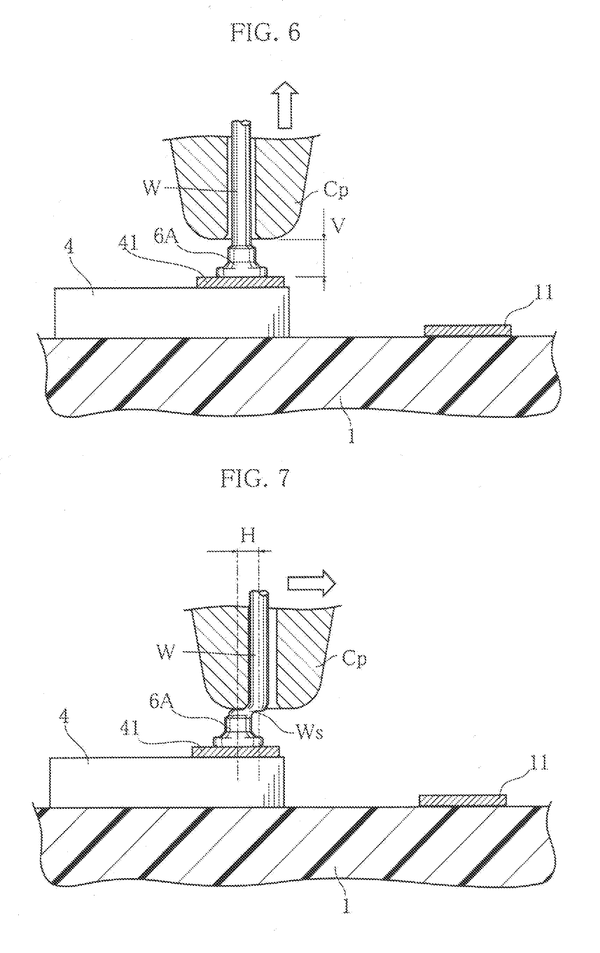

Then, as shown in FIG. 6, the capillary Cp is raised away from the electrode 41. While the capillary Cp is moved up, the wire W is dispensed from the capillary Cp so that the first bump 6A remains bonded to the electrode 41. The lifting of the capillary Cp is continued until the distance V between the end of the capillary Cp and the electrode 41 is 1.3 to 2.2 times the diameter of the wire W. The diameter of the wire W is about 30 μm, for example. In this instance, the distance over which the capillary Cp is moved is about 40 to 65 μm.

Then, as shown in FIG. 7, the capillary Cp is moved sideways, that is, in a direction perpendicular to the direction in which the capillary Cp is raised from the electrode 41. In this process, the temperature of the portion of the wire W that extends upward from the first bump 6A is still close to the melting point of Au. In this situation, the upwardly-extending portion of the wire W undergoes shear deformation due to the sideways movement of the capillary Cp. As a result, a neck or constriction Ws is formed above the first bump 6A. The cross sectional area of the neck Ws is considerably smaller than that of the first bump 6A and the nearby portion. To properly form the neck Ws, it is preferable to move the capillary Cp sideways by a distance H which is 1.0 to 1.7 times the diameter of the wire W. When the diameter of the wire W is about 30 μm, the distance H is about 30 to 50 μm.

Then, as shown in FIG. 8, the capillary Cp is raised further away from the electrode 41 as the wire W is being dispensed. In this process, the upward movement of the capillary Cp does not inflict any upward pull on the first bump 6A nor the neck Ws.

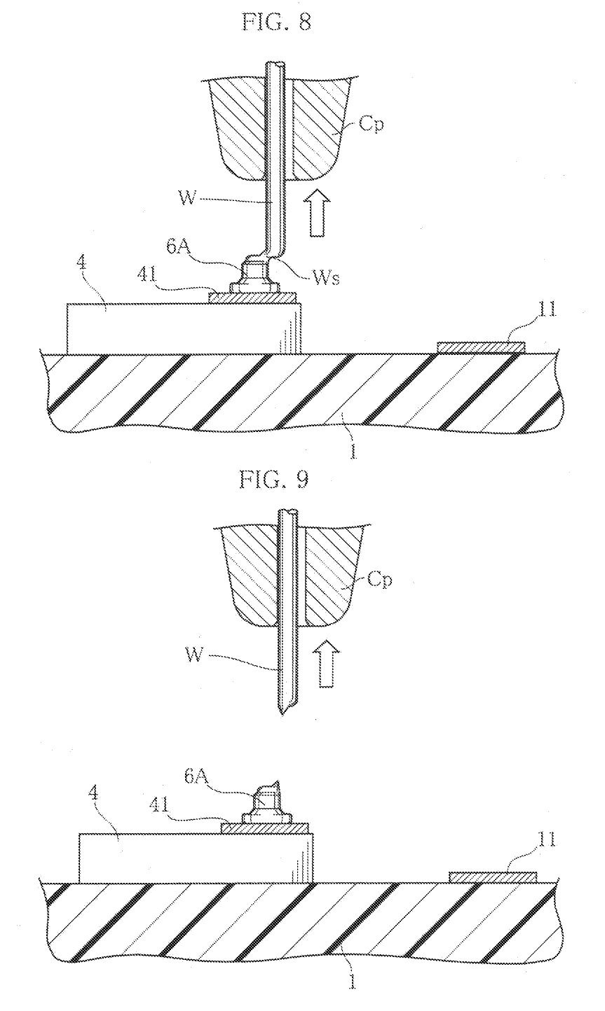

Then, as shown in FIG. 9, the dispensing of the wire W is stopped, while the capillary Cp continues to be moved away from the electrode 41. Accordingly, the wire W is pulled upward, applying a pulling force to the neck Ws. Since the cross sectional area of the neck Ws is considerably small, the neck Ws is broken apart by the pulling force, to result in a first bump 6A formed on the electrode 41.

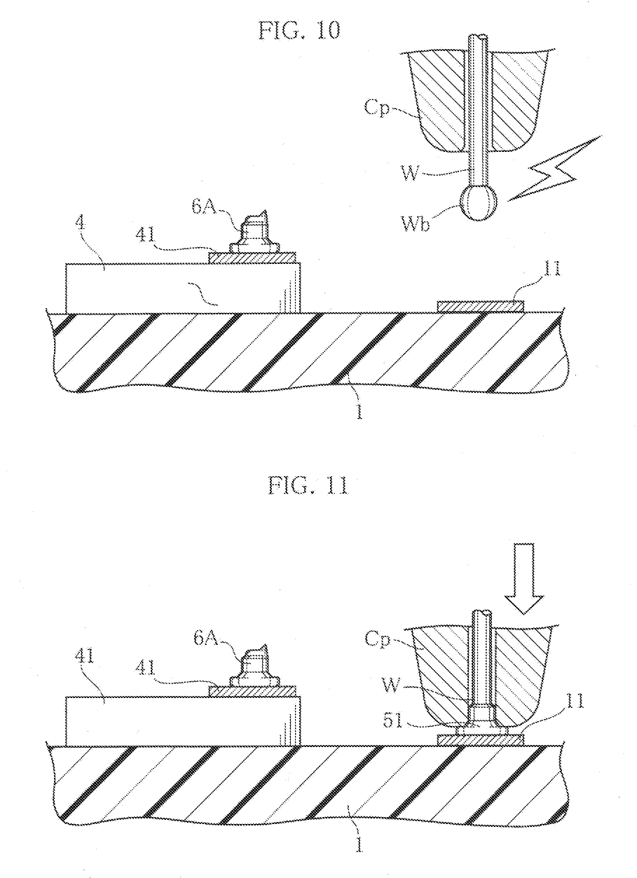

After the first bump 6A is formed, first bonding with respect to the bonding pad 11 is performed. Specifically, as shown in FIG. 10, the capillary Cp is positioned directly above the bonding pad 11, and a molten ball Wb is formed in the same manner as described above with reference to FIG. 4.

Then, as shown in FIG. 11, the capillary Cp is moved downward to press the molten ball Wb against the bonding pad 11. As a result, the molten ball Wb is formed into the first bonding portion 51.

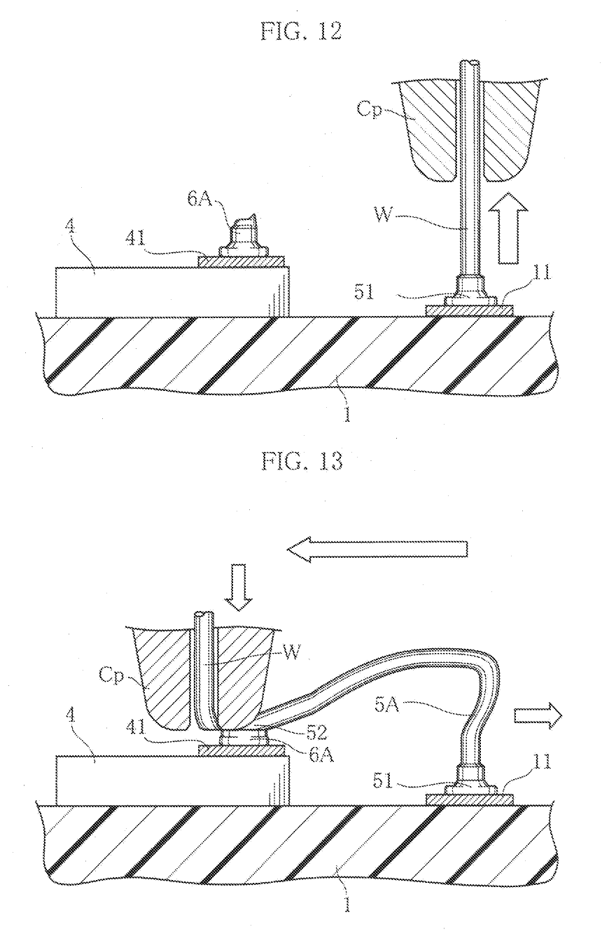

After the above first bonding is completed, the capillary Cp is moved upward, as shown in FIG. 12, with the wire W continuing to be dispensed. Then, second bonding with respect to the first bump 6A is performed, as shown in FIG. 13. Specifically, first, the capillary Cp is moved slightly to the right in the figure (that is, away from the first bump 6A). Then, the capillary Cp is moved to the left and downward, to reach the first bump 6A. Then, the capillary Cp is pressed against the first bump 6A, so that the portion of the wire W adjacent to the tip of the capillary Cp is compressed, almost broken apart, between the tip of the capillary Cp and the first bump 6A. Preferably, the pressing of the capillary Cp is performed while the capillary Cp is subjected to supersonic vibration. Continuous to the compressed portion, a wire 5A is provided to bridge the bonding pad 11 and the first bump 6A in the form of a horizontally stretched question mark. One end of the wire 5A that is bonded to the first bump 6A is a second bonding portion 52 having a wedge-shaped vertical section.

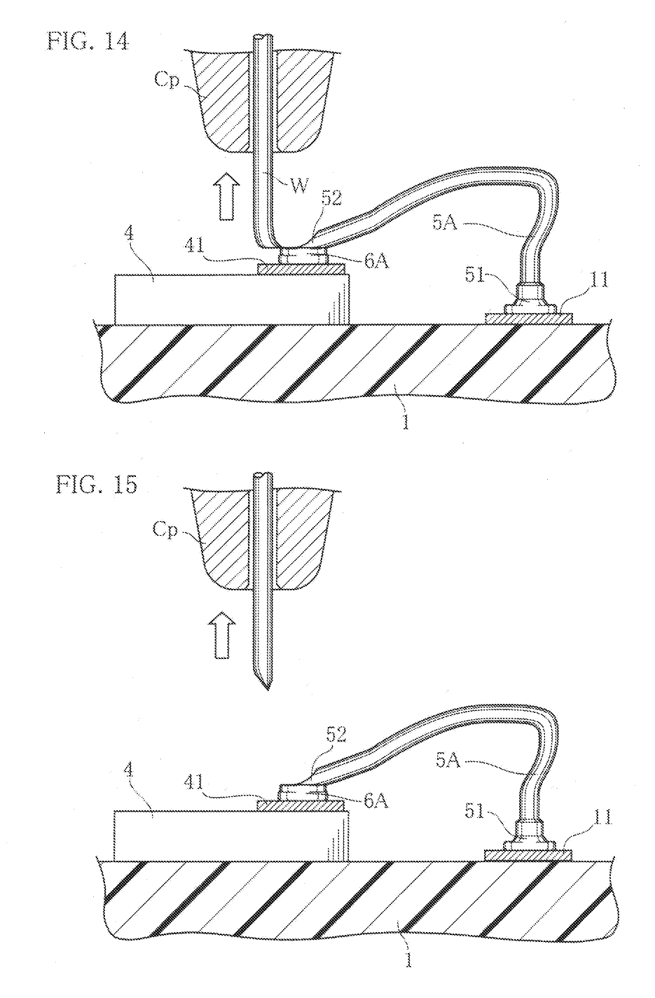

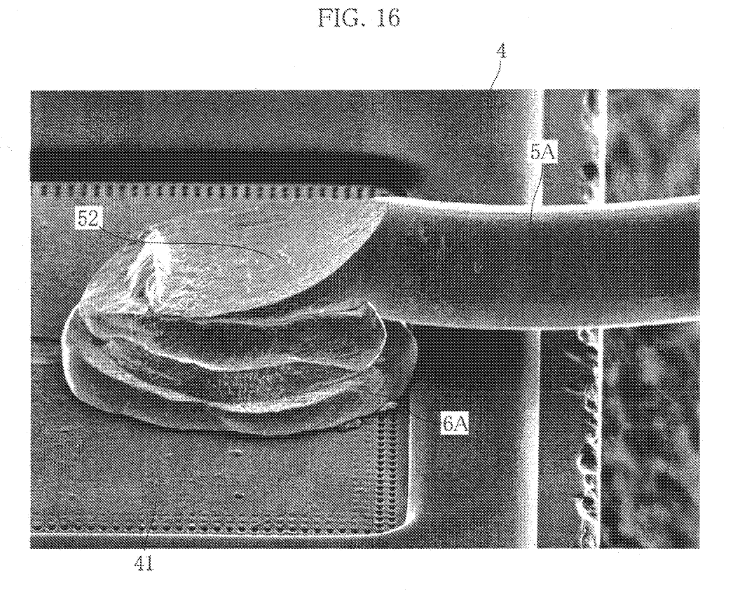

After pressed against the first bump 6A, the capillary Cp is raised up away from the electrode 41, as shown in FIG. 14, with the dispensing of the wire W continued. Then, as shown in FIG. 15, upon stopping the dispensing of the wire W, the capillary Cp is moved further away from the electrode 41. As a result, the wire W is completely separated from the first bump 6A and the wire 5A. Thus, the second bonding step comes to an end. FIG. 16 is an enlarged photograph showing the first bump 6A and the second bonding portion 52 after the second bonding step is completed. Due to the pressing by the capillary Cp, the first bump 6A has a flat shape.

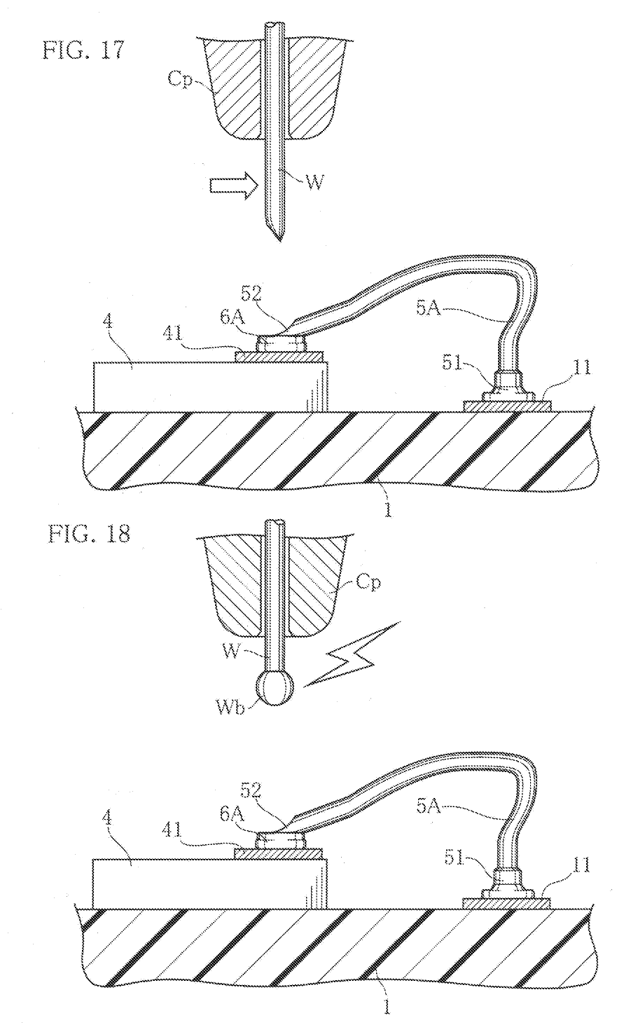

Then, as shown in FIG. 17, the capillary Cp is moved to the right so that the wire W projecting from the capillary Cp is positioned directly above the second bonding portion 52. Then, as shown in FIG. 18, by passing a spark, a molten ball Wb is formed at the end of the wire W.

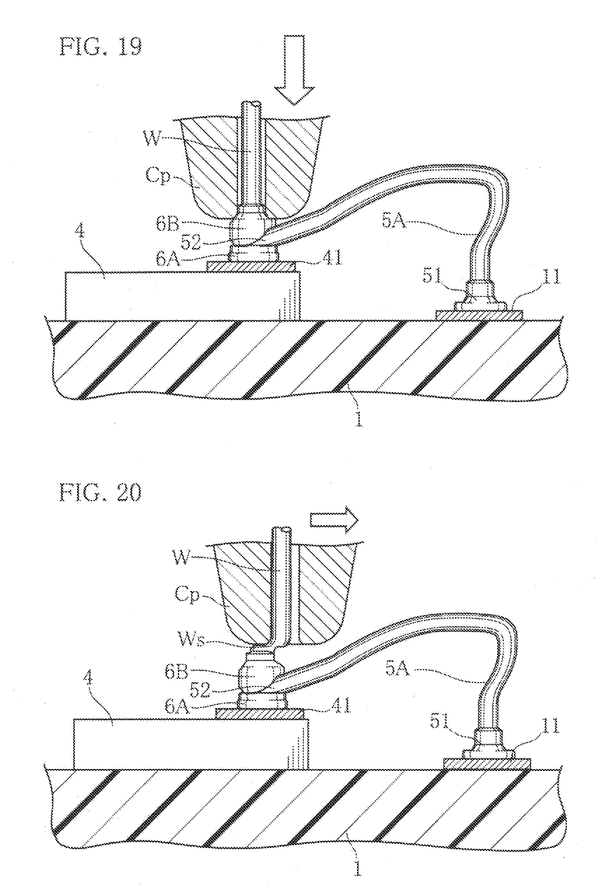

As shown in FIG. 19, the capillary Cp is lowered toward the electrode 41 until the molten ball Wb is compressed against the second bonding portion 51 and covers it. In this manner, the molten ball Wb is formed into a second bump 6B.

Then, after the capillary Cp is raised up from the electrode 41 with the wire W being dispensed, the capillary Cp is moved sideways, as shown in FIG. 20. The distances of the vertical movement and the horizontal movement of the capillary Cp in this process are the same as those described with reference to FIGS. 6 and 7. As a result, a neck Ws connected to the second bump 6B is formed.

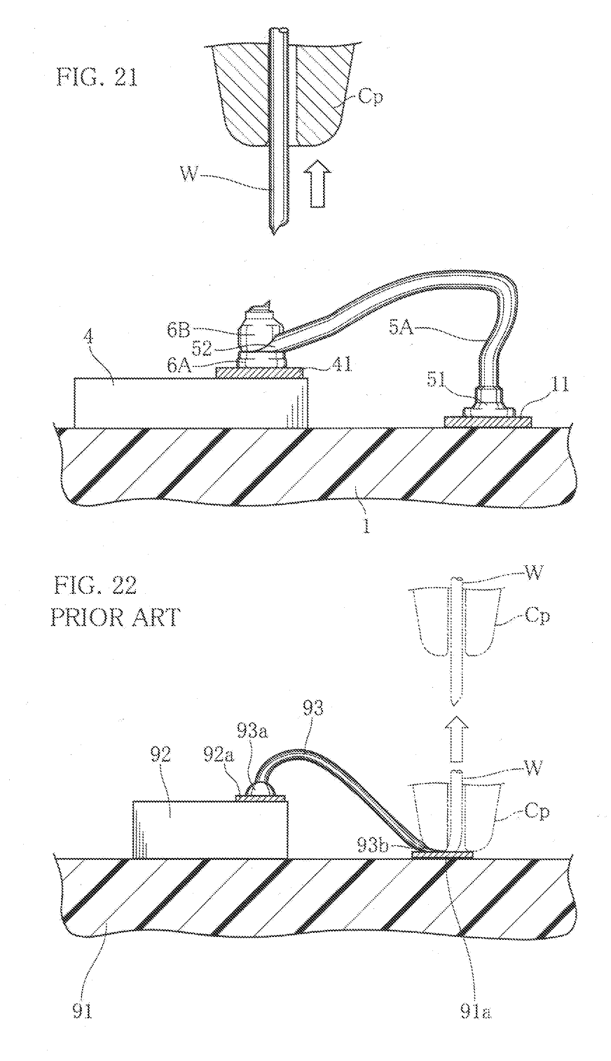

Then, as shown in FIG. 21, the wire W is broken at the neck Ws by moving the capillary Cp upward, whereby the second bump 6B is obtained.

The advantages of the infrared data communication module A and wire bonding method in manufacturing the infrared data communication module A will be described below.

According to the above-described embodiment, the wedge-shaped second bonding portion 52 is sandwiched between the first bump 6A and the second bump 6B, and these three members are collectively bonded to the electrode 41. Thus, stress does not concentrate on the wedge-shaped second bonding portion 52. In this connection, it should be noted that the resin package 7, made of a resin pervious to infrared rays, has a rather large coefficient of thermal expansion. With the above arrangement, even when a force to separate the wires 5A, 5B from the drive IC 4 is generated due to the thermal deformation of the resin package 7, the stress applied to the first bump 6A, the second bonding portion 52 and the second bump 6B is small. Therefore, the breakage of the wires 5A, 5B is prevented.

In forming the first bump 6A and the second bump 6B, a neck Ws is formed at the wire W by moving the capillary Cp horizontally. In separating the wire W from the first bump 6A or the second bump 6B, stress is concentrated on the neck Ws. Therefore, the bond between the first bump 6A and the electrode 41 or the bond between the second bump 6B and the second bonding portion 52 is not impaired, and hence the wires 5A, 5B are prevented from breaking.

The electronic component and the wire bonding method according to the present invention are not limited to the foregoing embodiment. The specific arrangement of the electronic component and the wire bonding method may be varied in many ways.

The electronic element in the present invention is not limited to a drive IC 4. For instance, the first bump 6A, the second bonding portion 52 and the second bump 6B may be formed on the electrode 31 of the light receiving element 3. Further, in addition to the drive IC and the light receiving element, the electronic element in the present invention includes various elements having an electrode to which a wire is to be bonded. The connection target is not limited to the electrode 41 nor the bonding pad 11. For instance, the connection target may be part of a lead frame. The electronic component in the present invention is not limited to the above-described infrared data communication module A and includes various electronic components such as a light receiving module which includes an electronic element to which a wire is connected.

1. An electronic component comprising:
an electronic element provided with an electrode;
a connection target connected to the electrode;
a wire including a first end and a second end opposite to the first end, the wire making a connection between the electrode and the connection target;
a first bump formed on the electrode; and
a second bump connected to the first bump;
wherein the first end of the wire includes a crown-shaped bonding portion held in contact with the connection target, the second end of the wire including a wedge-shaped bonding portion sandwiched between the first bump and the second bump.

2. A wire bonding method for connecting an electrode of an electronic component and a connection target to each other via a wire, the method comprising the steps of:
forming a first bump on the electrode of the electronic element;
bonding a first end of the wire to the connection target;
bonding a second end of the wire to the first bump; and
forming a second bump on the second end of the wire.
